(19) United States
(12) Patent Application Publication
(10) Pub. No.: US 2022/0187706 A1
(43) Pub. Date: Jun. 16, 2022

(54) THIN FILM RESIST COMPOSITION AND METHOD FOR MANUFACTURING RESIST FILM USING THE SAME

(71) Applicant: Merck Patent GmbH, Darmstadt (DE)

(72) Inventors: Shunji KAWATO, Kakegawa-shi (JP); Masato SUZUKI, Kakegawa-shi (JP); Tetsumasa TAKAICHI, Kakegawa-shi (JP); Takayuki SAO, Kakegawa-shi (JP); Taku HIRAYAMA, Tokyo (JP)

(21) Appl. No.: 17/442,835

(22) PCT Filed: Mar. 24, 2020
(86) PCT No.: PCT/EP2020/058109

§ 371 Date: Sep. 24, 2021

(30) Foreign Application Priority Data
Mar. 27, 2019 (JP) 2019-060630

(51) Int. Cl. G03F 7/004; G03F 7/039

(52) U.S. Cl. CPC G03F 7/0045; G03F 7/168; G03F 7/0392

(57) ABSTRACT

[Problem] Providing a thick film resist composition capable of reducing environmental impact. [Means for Solution] A thick film resist composition comprising polymer (A), a deprotecting agent (B), a photoreaction quencher (C) composed of a certain cation and an anion, and a solvent (D).

### BACKGROUND OF THE INVENTION

### Technical Field

The present invention relates to a thick film resist composition to be used in manufacturing semiconductor devices, semiconductor integrated circuits, and the like, and a method for manufacturing a resist film using the same.

### Background Art

In a process of manufacturing a device such as a semiconductor, fine processing by lithographic technique using a photoresist has generally been employed. The fine processing process comprises forming a thin photoresist layer on a semiconductor substrate such as a silicon wafer, covering the layer with a mask pattern corresponding to a desired device pattern, exposing the layer with actinic ray such as ultraviolet ray through the mask, developing the exposed layer to obtain a photoresist pattern, and etching the substrate using the resulting photoresist pattern as a protective film, thereby forming fine unevenness corresponding to the above-described pattern.

While requiring making finer the resist pattern, there is a demand for a resist pattern that is thicker and has a higher aspect ratio in order to cope with high-energy ion implantation and the like. When forming a thick film resist pattern, unlike the case of a thin film, the performance and process conditions required for the composition are different. Therefore, the required form cannot be formed only by adjusting the viscosity of the thin film resist composition to make it thicker, so that there are characteristic difficulties.

For example, there is a method for increasing the viscosity of the composition in order to obtain a thick resist film, but there is a phenomenon that a high load is applied to the total liquid of the composition or uniformity of the film thickness cannot be obtained. Patent Document 1 studies a chemical solution for photolithography containing a resin component having a certain low molecular weight and an organic solvent having a predetermined saturated vapor pressure and viscosity.

Patent Document 2 describes that when the film thickness is thicker, the accuracy of a device formed from a resist pattern having a cross section that is not rectangular sometimes deteriorates. Patent Document 2 studies, for the purpose of obtaining a composition that forms a pattern whose sectional shape is close to a rectangle even if it is a thick film, a composition comprising a chemically amplified polymer, a first photoacid generator and a second photoacid generator. These plural acid generators act on the chemically amplified polymer to deprotect the polymer and increase alkali solubility.

When a chemically amplified resist is used, if the time from exposure to post exposure bake becomes longer, the shape of the resist pattern sometimes changes due to environmental impact such as amines in the air. On the other hand, a technique for reducing the impact by adding a base compound such as amine to the composition is known. For example, Patent Document 3 studies addition of tri-n-hexylamine or the like for acid diffusion control although it is for a film thickness of 0.7 μm.

### PRIOR ART DOCUMENTS

### Patent Documents

[Patent document 1] JP-A 2016-206673

[Patent document 2] JP-A 2018-109701

[Patent document 3] JP-B 3677963

### Non-Patent Document

[Non-patent document 1] Clean room cleanliness management support (SCAS news 2006, p 11-14)

### SUMMARY OF THE INVENTION

### Problems to be Solved by the Invention

The present inventors considered that there are one or more problems still need improvements in resist compositions and use thereof. These include, for example, the followings: coating properties of the composition is insufficient; sensitivity is insufficient; sufficient resolution cannot be obtained; the composition largely receives environmental impact in the manufacturing process; the composition receives environmental impact during from exposure to post exposure bake, and the space between tops of the pattern and/or that between bottoms of the pattern shrink greatly; poor film formation and/or crack generation make it impossible to form a thick film; the resist pattern has low aspect ratio; the solid components have poor solubility in the solvent; the number of defects is large; storage stability is poor; and etching resistance of the resist film is insufficient.

The present invention has been made based on the technical background as described above, and provides a thick film resist composition and a method for manufacturing a resist film using the same.

### Means for Solving the Problems

The thick film resist composition according to the present invention comprises polymer (A), a deprotecting agent (B), a photoreaction quencher (C), and a solvent
(D),
wherein the photoreaction quencher (C) is represented by the formula (C-1):

C^{m+}cation C^{m-}anion (C-1)

wherein,

C^{m+}cation consists of at least one cation selected from the group consisting of a cation represented by the formula (CC1) and a cation represented by the formula (CC2), and is m-valent as a whole (where m is 1 to 3):

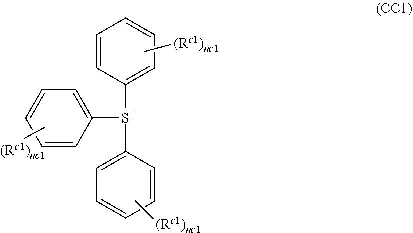

(wherein,
R^{c1} each independently represents C₁₋₆ alkyl, C₁₋₆ alkoxy or C₆₋₁₂ aryl, and
nc1 is each independently 0, 1, 2, or 3),

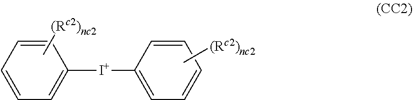

(wherein,
R^{c2} is each independently C₁₋₆ alkyl, C₁₋₆ alkoxy or C₆₋₁₂ aryl, and
nc2 is each independently 0, 1, 2, or 3); and

C^{m-}anion consists of at least one anion selected from an anion represented by the formula (CA) and is m-valent as a whole:

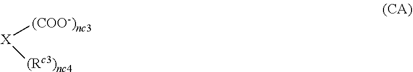

(wherein,
X is a C₁₋₂₀ hydrocarbon group,
R^{c3} is each independently hydroxy, C₁₋₆ alkyl or C₆₋₁₀ aryl,
nc3 is 1, 2 or 3, and
nc4 is 0, 1 or 2).

Further, the method for manufacturing a resist film according to the present invention comprises the following processes:

(1) applying the above-described composition above a substrate; and

(2) heating the composition to form a resist film

### Effects of the Invention

Using the thick film resist composition of the present invention, one or more of the following effects can be desired.

A composition having good coating properties can be obtained. A film having sufficient sensitivity can be obtained. Sufficient resolution can be obtained. Environmental impact in the manufacturing process can be reduced. Environmental impact during from exposure to post exposure bake can be reduced, and shrinkage of the space between tops of the pattern and/or that between bottoms of the pattern can be suppressed. A thick resist film can be formed by good film formation and/or crack suppression. A resist pattern having a high aspect ratio can be formed. Solubility of the solid components in the solvent is good. The number of defects can be reduced. Storage stability is good. A resist film having high etching resistance can be obtained.

### BRIEF DESCRIPTION OF THE DRAWINGS

FIG. 1 Schematic views showing a sectional shape of a resist pattern when PED is short and a sectional shape of a resist pattern when PED is long.

### DETAILED DESCRIPTION OF THE INVENTION

### MODE FOR CARRYING OUT THE INVENTION

Definitions

Unless otherwise specified in the present specification, the definitions and examples described in this “Definitions” paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has a plural types of repeating units, these repeating units copolymerize. These copolymerization may be any of alternating copolymerization, random copolymerization, block copolymerization, graft copolymerization, or any combination of any of these. When polymer or resin is represented by a structural formula, n, m or the like that is attached next to parentheses indicate the number of repetitions.

Celsius is used as the temperature unit. For example, 20 degrees means 20 degrees Celsius.

Embodiments of the present invention are described below in detail.

<Thick Film Resist Composition>

The thick film resist composition according to the present invention (hereinafter sometimes referred to as the composition) comprises polymer(A), a deprotecting agent (B), a photoreaction quencher (C), and a solvent (D).

The thick film resist composition means a resist composition capable of forming a thick resist film. Here, in the present invention, the thick film means a film having a thickness of 1 to 25 μm (preferably 1.5 to 20 μm), and the thin film means a film having a thickness of less than 1 μm.

The viscosity of the composition according to the present invention is preferably 5 to 900 cP, and more preferably 7 to 700 cP. Here, the viscosity is measured at 25° C. with a capillary viscometer.

The composition according to the present invention is preferably a positive type chemically amplified thick film resist composition.

For the composition according to the present invention, a light source of 248 nm±1% or 193 nm±1% is preferably used upon exposure to be performed later.

(A) Polymer

The polymer used in the present invention reacts with an acid to increase the solubility in an alkaline aqueous solution. This kind of polymer has, for example, an acid group protected by a protecting group, and when an acid is added from the outside, the protecting group is eliminated and the solubility in an alkaline aqueous solution increases. This kind of polymer can be freely selected from those generally used in lithography method.

In the present invention, among the polymer (A), those comprising at least one structural unit selected from the group consisting of the structural units represented by the following formulae (P-1), (P-2) and (P-3) are preferred.

The formula (P-1) is as shown below:

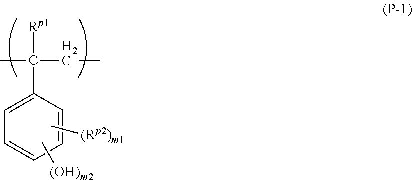

wherein,
R^{p1} is hydrogen, C₁₋₅ alkyl, C₁₋₅ alkoxy or —COON,
R^{p2} is C₁₋₅ alkyl (where —CH₂— can be replaced with —O—)
m1 is a number of 0 to 4, and
m2 is a number of 1 to 2, and m1+m2≤5.

In one embodiment of the polymer (A) of the present invention, it is possible that the polymer has only (P-1) as a structural unit and that the ratio of (P-1) wherein m2=1 and (P-1) wherein m2=2 is 1:1. In this case, it becomes that m2=1.5. Hereinafter, the same applies to any polymer unless otherwise specified.

R^{p1} is preferably hydrogen or methyl, and more preferably hydrogen.

R^{p2} is preferably methyl, ethyl or methoxy, and more preferably methyl.
m2 is preferably 1.
m1 is preferably 0.

An exemplified embodiment of the formula (P-1) is as shown below:

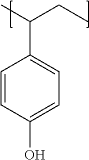

The formula (P-2) is as shown below:

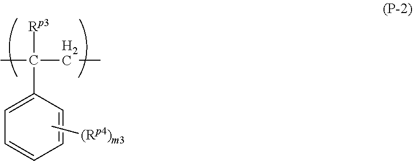

wherein,
R^{p3} is hydrogen, C₁₋₅ alkyl, C₁₋₅ alkoxy or —COON;
R^{p4} is C₁₋₅ alkyl or C₁₋₅ alkoxy (where —CH₂— contained in alkyl or alkoxy can be replaced with —O—), and m3 is a number of 0 to 5.

R^{p3} is preferably hydrogen or methyl, and more preferably hydrogen.

R^{p4} is C₁₋₅ alkoxy (where —CH₂— contained in alkoxy can be replaced with —O—), and at this time, m3 is preferably 1.

R^{p4} in this aspect includes methoxy, t-butyloxy and —O—CH(CH₃)—O—CH₂CH₃.

m3 is preferably 0, 1, 2, 3, 4 or 5, and more preferably 0 or 1. It is also a preferable aspect that m3 is 0.

Exemplified examples of the formula (P-2) are as shown below:

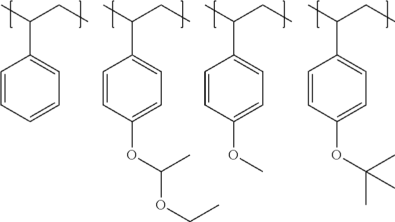

The formula (P-3) is as shown below:

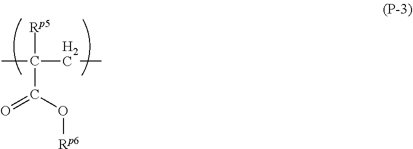

wherein,
R^{p5} is hydrogen, C₁₋₅ alkyl, C₁₋₅ alkoxy or —COOH, and
R^{p6} is C₁₋₁₅ alkyl or C₁₋₅ alkyl ether (preferably C₁₋₁₅ alkyl) and R^{p6} can have a cyclic structure. Here, alkyl moiety of R^{p6} is preferably branched or cyclic.

R^{p5} is preferably hydrogen, methyl, ethyl, methoxy or —COOH, more preferably hydrogen or methyl, and further preferably hydrogen.

R^{p6} is preferably methyl, isopropyl, t-butyl, cyclopentyl, methylcyclopentyl, ethylcyclopentyl, methylcyclohexyl, ethylcyclohexyl, methyladamantyl or ethyladamantyl, more preferably t-butyl, ethylcyclopentyl, ethylcyclohexyl or ethyl adamantyl, and further preferably t-butyl.

Exemplified examples of the formula (P-3) are as shown below:

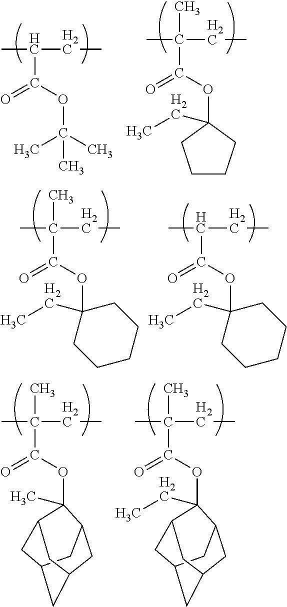

Since these structural units are appropriately blended depending on the purpose, the blending ratio thereof is not particularly limited, but they are preferably blended so that the increasing ratio of the solubility in an alkaline aqueous solution is made appropriate by an acid.

Preferably, nₚ₁, nₚ2 and nₚ₃, which are the repetition numbers respectively of the formulae (P1), (P2) and (P3), satisfy the following formulae:

40%≤nₚ₁/(nₚ₁+nₚ₂+nₚ₃)≤80%,

3%≤nₚ₂/(nₚ₁+nₚ₂+nₚ₃)≤40%, and/or

10%≤nₚ₃/(nₚ₁+nₚ₂+nₚ₃)≤40%

nₚ₁/(nₚ₁+nₚ₂+nₚ₃) is more preferably 50 to 80%, further preferably 55 to 75%, and still more preferably 60 to 70%.

nₚ₂/(nₚ₁+nₚ₂+nₚ₃) is more preferably 3 to 30%, further preferably 5 to 25%, and still more preferably 10 to 20%.

nₚ₃/(nₚ₁+nₚ₂+nₚ₃) is more preferably 10 to 25%, further preferably 12 to 25%, and still more preferably 10 to 20%.

The polymer (A) can also comprise structural units other than (P-1) to (P-3), but it is preferable that the total number (nₜₒₜₐₗ) of all repeating units contained in the polymer (A) satisfies the following formula:

80%≤(nₚ₁+nₚ₂+nₚ₃)/nₜₒₜₐₗ≤100%.

(nₚ₁+nₚ₂+nₚ₃)/nₜₒₜₐₗ is more preferably 90 to 100%, and further preferably 95 to 100%. It is also a preferred aspect of the present invention that (nₚ₁+nₚ₂+nₚ₃)/nₜₒₜₐₗ=100%, that is, any structural unit other than (P-1), (P-2) and (P-3) is not contained.

Exemplified examples of the polymer (A) are as shown below:

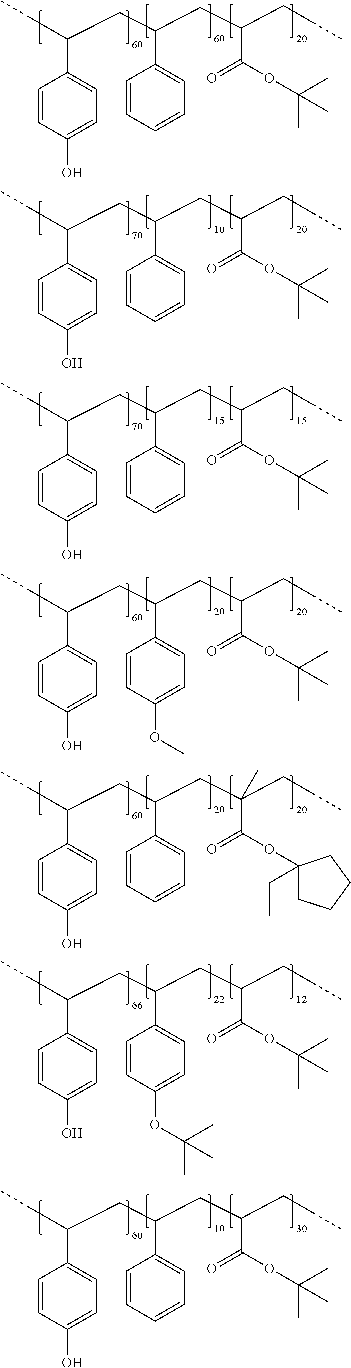

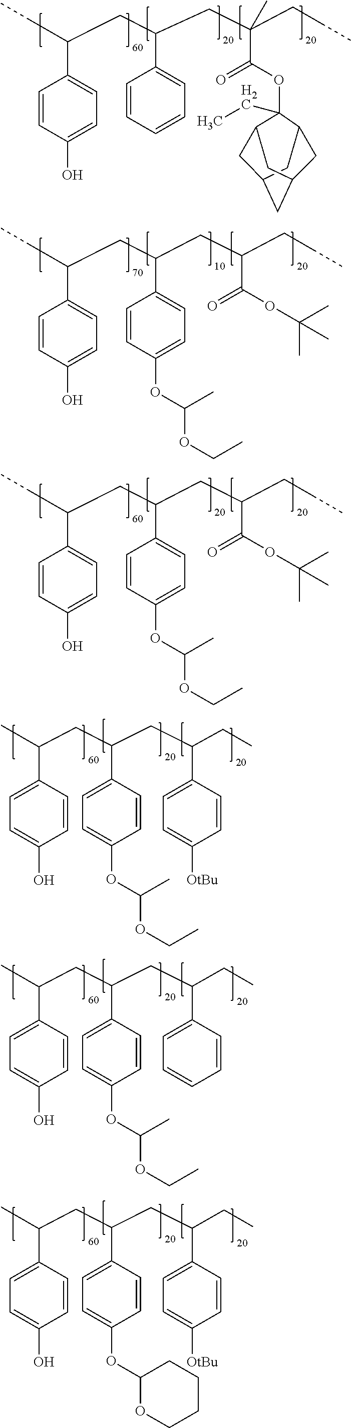

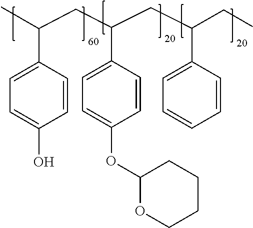

The mass average molecular weight (hereinafter sometimes referred to as Mw) of the polymer (A) is preferably 5,000 to 50,000, more preferably 5,000 to 25,000, and further preferably 5,000 to 20,000.

The number average molecular weight (hereinafter sometimes referred to as Mn) of the polymer (A) is preferably 1,600 to 39,000, and more preferably 1,600 to 20,000.

In the present invention, Mw and Mn can be measured by gel permeation chromatography (GPC). In this measurement, it is a preferable example to use a GPC column at 40 degrees Celsius, an elution solvent tetrahydrofuran at 0.6 mL/min, and monodisperse polystyrene as a standard.

For the sake of clarity it is noted that, in the compositions of the present invention, these polymer can be used in any combination of any two or more of them as long as they are represented by the above formulae. For example, a composition containing both of the following two types of the polymer (A) is also one embodiment of the present invention:

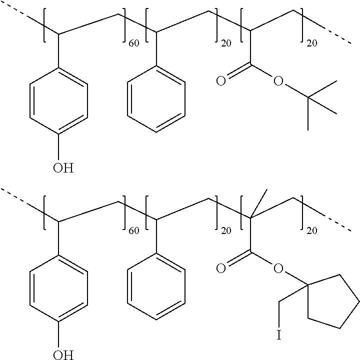

In addition, for example, a composition containing both of the following two types of the polymer (A) is also an embodiment of the present invention:

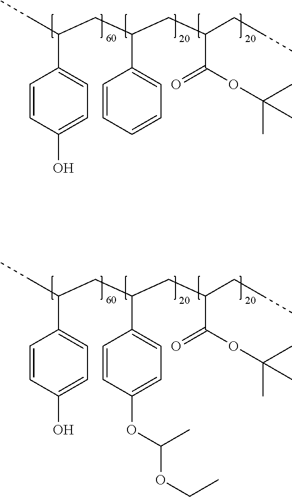

In addition, for example, a composition containing both of the following two types of the polymer (A) is also an embodiment of the present invention:

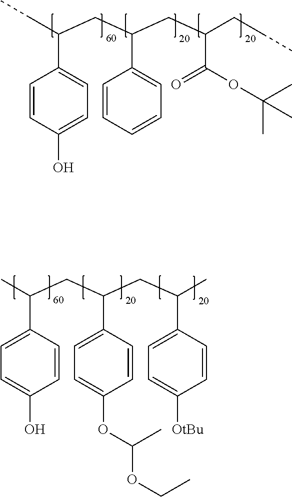

In addition, for example, a composition containing both of the following two types of the polymer (A) is also an embodiment of the present invention:

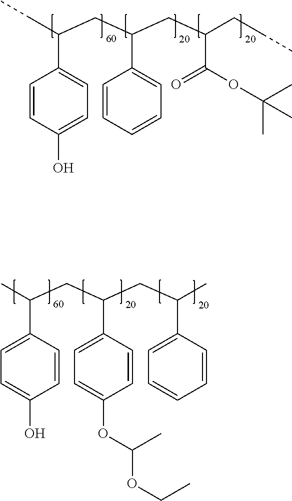

Preferably, the polymer (A) contained in the composition according to the present invention consists of one or two kinds of polymer, and more preferably, the polymer (A) consists of one kind of polymer. For the sake of clarity it is noted that, variation in Mw distribution or polymerization is accepted.

The content of the polymer (A) is preferably 10 to 60 mass %, and more preferably 15 to 60 mass %, and further preferably 15 to 50 mass %, based on the total mass of the composition.

The composition according to the present invention accepts to contain other polymer than the polymer (A). The other polymer than the polymer (A) is a polymer that does not satisfy the conditions that at least one structural unit selected from the group consisting of the structural units represented by the above formulae (P-1), (P-2) and (P-3) is contained.

The aspect that any polymer other than the polymer (A) is not contained is a preferred embodiment of the composition according to the present invention.

(B) Deprotecting Agent

The composition according to the present invention comprises a deprotecting agent. The deprotecting agent releases an acid by irradiation with light, and the acid acts on the polymer to play a role of increasing the solubility of the polymer in an alkaline aqueous solution. For example, when the polymer has an acid group protected by a protecting group, the protecting group is eliminated with an acid. The deprotecting agent used in the composition according to the invention can be selected from those conventionally known.

In the present invention, the deprotecting agent means a compound itself having the above-described function. Although the compound is sometimes dissolved or dispersed in a solvent and contained in the composition, such a solvent is preferably contained in the composition as the solvent (D) or other component. Hereinafter, the same applies to various additives that can be contained in the composition.

The deprotecting agent (B) releases an acid having an acid dissociation constant pKa (H₂O) of −20 to 1.4, more preferably −16 to 1.4, further preferably −16 to 1.2, and still more preferably −16 to 1.1, upon exposure.

Preferably, the deprotecting agent (B) is represented by the formula (B-1):

Bⁿ⁺cation Bⁿ⁻anion (B-1)

wherein,

Bⁿ⁺cation consists of at least one cation selected from the group consisting of a cation represented by the formula (BC1), a cation represented by the formula (BC2) and a cation represented by the formula (BC3), and is n-valent as a whole (where n is 1 to 3), and

Bⁿ⁻anion consists of at least one anion selected from the group consisting of an anion represented by the formula (BA1), an anion represented by the formula (BA2), an anion represented by the formula (BA3) and an anion represented by the formula (BA4), and is n-valent as a whole.

n-valent is preferably monovalent or bivalent, and more preferably monovalent.

The formula (BC1) is as shown below:

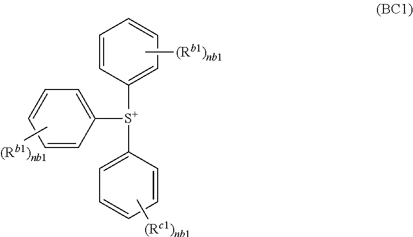

wherein,
R^{b1} is each independently C₁₋₆ alkyl, C₁₋₆ alkoxy, C₆₋₁₂ aryl, C₆₋₁₂ arylthio or C₆₋₁₂ aryloxy, and
nb1 is each independently 0, 1, 2 or 3.

R^{b1} is preferably methyl, ethyl, t-butyl, methoxy, ethoxy, phenylthio or phenyloxy, and more preferably t-butyl, methoxy, ethoxy, phenylthio or phenyloxy.

It is also a preferable aspect that all nb1 are 1 and all R^{b1} are identical.

Further, it is also a preferable aspect that nb1 is 0.

Exemplified examples of the formula (BC1) are as shown below:

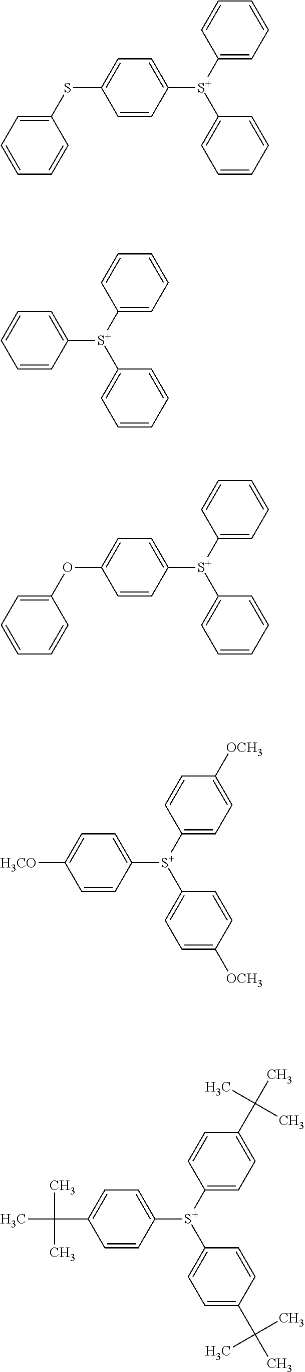 [SMILES: c1ccc(Sc2ccc([S+](c3ccccc3)c3ccccc3)cc2)cc1 ; c1ccc([S+](c2ccccc2)c2ccccc2)cc1 ; c1ccc(Oc2ccc([S+](c3ccccc3)c3ccccc3)cc2)cc1 ; COc1ccc([S+](c2ccc(OC)cc2)c2ccc(OC)cc2)cc1 ; CC(C)(C)c1ccc([S+](c2ccc(C(C)(C)C)cc2)c2ccc(C(C)(C)C)cc2)cc1]

The formula (BC2) is as shown below:

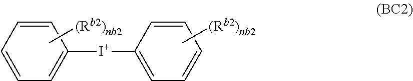

wherein,
R^{b2} is each independently C₁₋₆ alkyl, C₁₋₆ alkoxy or C₆₋₁₂ aryl, and
nb2 is each independently 0, 1, 2 or 3.

R^{b2} is preferably alkyl having a C₄₋₆ branched structure. Each R^{b2} in the formula can be identical or different, and more preferably identical. R^{b2} is further preferably t-butyl or 1,1-dimethylpropyl, and still more preferably t-butyl.

nb2 is each preferably 1.

Exemplified examples of the formula (BC2) are as shown below:

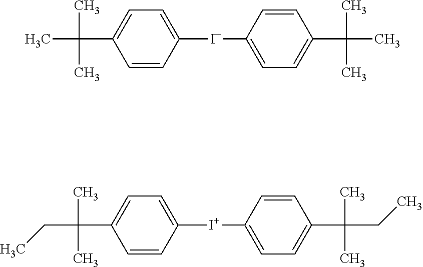

The formula (BC3) is as shown below:

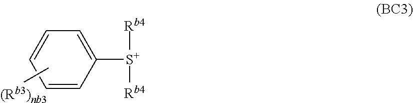

wherein,
R^{b3} is each independently C₁₋₆ alkyl, C₁₋₆ alkoxy or C₆₋₁₂ aryl,
R^{b4} is each independently C₁₋₆ alkyl, and
nb3 is each independently 0, 1, 2 or 3.

R^{b3} is preferably methyl, ethyl, methoxy or ethoxy, and more preferably methyl or methoxy. For the sake of clarity it is noted that, plural R^{b3} can be different from each other.

R^{b4} is preferably methyl or ethyl, and more preferably methyl.

nb3 is preferably 1, 2 or 3, and more preferably 3.

An exemplified embodiment of the formula (BC3) is as shown below:

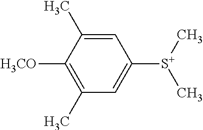

The Bⁿ⁺cation is preferably selected from the group consisting of a cation represented by the formula (BC1) or (BC2), since it exhibits a more remarkable effect.

The formula (BA1) is as shown below:

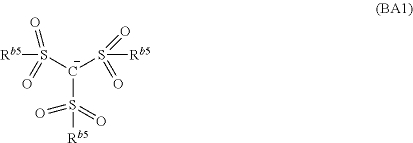

wherein,
R^{b5} is each independently C₁₋₆ fluorine-substituted alkyl or C₁₋₆ alkyl.

For example, —CF₃ means methyl (C₁) in which hydrogen is replaced with fluorine. Preferably, all of the hydrogen present in C₁₋₆ fluorine-substituted alkyl is replaced with fluorine.

The alkyl moiety of R^{b5} is preferably methyl, ethyl or t-butyl, and more preferably methyl.

R^{b5} is preferably fluorine-substituted alkyl, and more preferably —CF₃.

An exemplified embodiment of the formula (BA1) is as shown below:

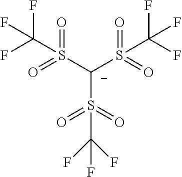 [SMILES: O=S(=O)([C-](S(=O)(=O)C(F)(F)F)S(=O)(=O)C(F)(F)F)C(F)(F)F]

The formula (BA2) is as shown below:

R^{b6}—SO₃⁻ (BA2)
wherein,
R^{b6} is C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl.

For example, —CF₃ means methyl (C₁) in which hydrogen is replaced with fluorine. Preferably, all of the hydrogen present in C₁₋₆ fluorine-substituted alkyl is replaced with fluorine.

The alkyl moiety of R^{b6} is preferably methyl, ethyl, propyl, butyl or pentyl, more preferably propyl, butyl or pentyl, and further preferably butyl.

The alkyl moiety of R^{b6} is preferably linear. R^{b6} is preferably C₁₋₆ fluorine-substituted alkyl.

R^{b6} is preferably C₂₋₆ fluorine-substituted alkyl.

Exemplified examples of the formula (BA2) are as shown below:

C₄F₉SO₃—, C₃F₇SO₃—

The formula (BA3) is as shown below:

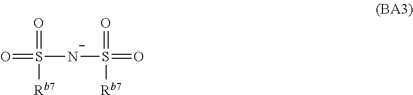

wherein,
R^{b7} is each independently C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl, where two R^{b7} can be bonded to each other to form a fluorine-substituted heterocyclic structure.

For example, —CF₃ means methyl (C₁) in which hydrogen is replaced with fluorine. Preferably, all of the hydrogen present in C₁₋₆ fluorine-substituted alkyl is replaced with fluorine.

The alkyl moiety of R^{b7} is preferably methyl, ethyl, propyl, butyl or pentyl, more preferably methyl, ethyl or butyl, and further preferably butyl. The alkyl moiety of R^{b6} is preferably linear.

R^{b7} is preferably C₂₋₆ fluorine-substituted alkyl.

It is also preferable that two R^{b7} are bonded to each other to form a fluorine-substituted heterocyclic structure, and in this case, the heterocyclic ring can be monocyclic or polycyclic. Preferably, it is a monocyclic structure having 5 to 8 members.

Exemplified examples of the formula (BA3) are as shown below:

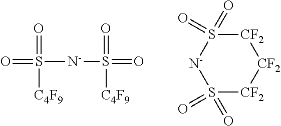

The formula (BA4) is as shown below:

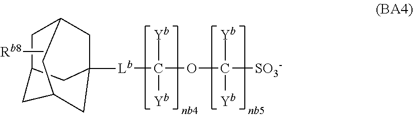

wherein,
R^{b8} is hydrogen, C₁₋₆ alkyl, C₁₋₆ alkoxy or hydroxy,
L^{b} is carbonyl, oxy or carbonyloxy,
Y^{b} is each independently hydrogen or fluorine,
nb4 is an integer of 0 to 10, and
nb5 is an integer of 0 to 21.

R^{b8} is preferably hydrogen, methyl, ethyl, methoxy or hydroxy, and more preferably hydrogen or hydroxy.

L^{b} is preferably carbonyl or carbonyloxy, and more preferably carbonyl.

Preferably, at least one of Y^{b} is fluorine.

nb4 is preferably 0.

nb5 is preferably 4, 5 or 6.

Exemplified examples of the formula (BA4) are as shown below:

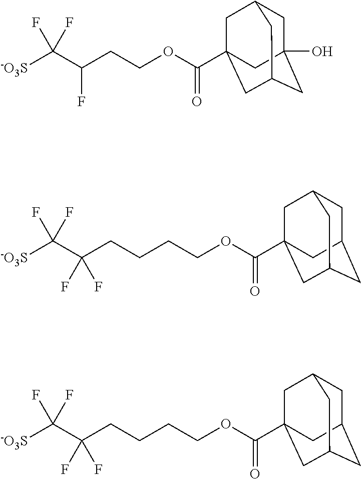

The molecular weight of the deprotecting agent (B) is preferably 400 to 2,500, and more preferably 400 to 1,500.

The content of the deprotecting agent (B) is preferably 0.05 to 5 mass %, and more preferably 0.1 to 4 mass %, based on the total mass of the polymer (A).

As the deprotecting agent (B), known ones can be used as long as the acid generated by exposure can deprotect the protecting group of the polymer (A). For example, one having the acid dissociation constant pKa upon exposure (H₂O) of −20 to 1.4 is preferred as described above. Known ones include photoacid generators, for example, acid generators that generate strong acids.

(C) Photoreaction Quencher

The composition according to the present invention comprises a photoreaction quencher. The photoreaction quencher releases an acid upon irradiation with light, but the acid does not act directly on the polymer. In this respect, it is different from the deprotecting agent (B), which has a direct action on the polymer by eliminating the protecting group of the polymer with the released acid.

The photoreaction quencher (C) functions as a quencher that suppresses the diffusion of the acid derived from the deprotecting agent (B) generated in the exposed area. Although not to be bound by theory, the following mechanism is considered for this. When the acid is released from the deprotecting agent (B) upon exposure and this acid diffuses into the unexposed area (the area that is not exposed), salt exchange with the photoreaction quencher (C) occurs. That is, the anion of the deprotecting agent and the cation of the photoreaction quencher (C) form a salt. Thereby, the diffusion of the acid is suppressed. At this time, the anion of the photoreaction quencher (C) is released, but since this is a weak acid and cannot be deprotected the polymer, it can be considered that there is no effect on the unexposed area.

Furthermore, the photoreaction quencher (C) has an effect of suppressing acid deactivation on the resist film surface by components such as amines contained in the air. Although not to be bound by theory, the following mechanism is considered for this. In the exposed area, an acid (a weak acid derived from the photoreaction quencher (C) and an acid derived from the deprotecting agent (B)) is generated upon exposure. Through penetration of the amine in the air into the resist film surface, the acid present therein is neutralized. However, the weak acid released from the photoreaction quencher (C) is present, so that the frequency that the acid released from the deprotecting (B) agent is neutralized is reduced. Thus, it is considered that the deactivation of an acid is suppressed by increasing the acid in an exposed area.

The composition according to the present invention includes a photoreaction quencher (C), so that, as is described later, it is considered that the composition is not easily changed in shape even if the PED after exposure becomes longer.

In order to obtain the above two effects, it has been common in the prior art to add a basic compound such as a tertiary amine. In the case that the composition contains a photoreaction quencher (C), there is a tendency that the above two effects are higher and the sensitivity are higher than in the case that the composition contains a basic compound. Although not to be bound by theory, it is considered that when the basic compound is added as a quencher for the acid that diffuses from the exposed area to the unexposed area, the acid is neutralized (quenched) even in the exposed area. Further, although not to be bound by theory, when the basic compound is added to suppress the deactivation of the acid on the resist film surface due to the influence of the components such as amine contained in the air, the amount of amine that has penetrated from the air is relatively reduced due to the presence of the basic composition in the film. On the other hand, it is not intentionally to control the penetration of amines in the air. In this way, it is considered that using the photoreaction quencher (C) as in the present invention is more suitable for resist pattern design and stable production. As described above, the assumed action mechanism differs between when a basic compound is added and when a photoreaction quencher is added.

Although not to be bound by theory, when the photoreaction quencher (C) is solid, it is considered that a stable effect can be obtained because it is more dispersible in the film than the basic compound.

The photoreaction quencher (C) releases an acid having an acid dissociation constant pKa (H₂O) of preferably 1.5 to 8, and more preferably 1.5 to 5, upon exposure.

The photoreaction quencher (C) is represented by the formula (C-1):

C^{m+}cation C^{m-}anion (C-1)

wherein,

C^{m+}cation consists of at least one cation selected from the group consisting of a cation represented by the formula (CC1) and a cation represented by the formula (CC2), and is m-valent as a whole (where m is 1 to 3), and

C^{m-}anion consists of at least one anion selected from an anion represented by the formula (CA) and is m-valent as a whole.

m-valent is preferably monovalent or bivalent, and more preferably monovalent.

The formula (CC1) is as shown below:

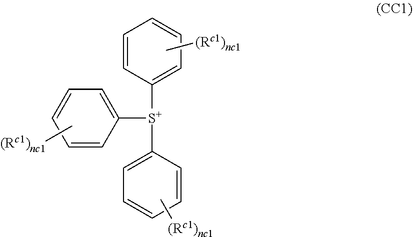

wherein,
R^{c1} each independently represents C₁₋₆ alkyl, C₁₋₆ alkoxy or C₆₋₁₂ aryl, and
nc1 is each independently 0, 1, 2, or 3.

R^{c1} is preferably methyl, ethyl, t-butyl, methoxy, ethoxy, phenylthio or phenyloxy, more preferably t-butyl, methoxy, ethoxy, phenylthio, phenyloxy, and further preferably t-butyl or methoxy.

It is also a preferable aspect that all nc1 are 1 and all R^{c1} are identical.

Further, it is also a preferred aspect that nc1 is 0.

Exemplified examples of the formula (CC1) are as shown below:

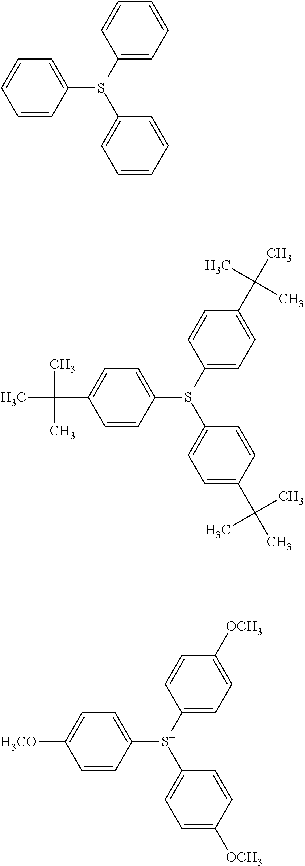 [SMILES: c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; COc1ccc([S+](c2ccc(OC)cc2)c2ccc(OC)cc2)cc1]

The formula (CC2) is as shown below:

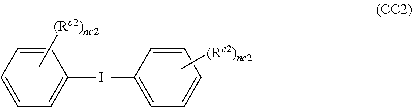

wherein,
R^{c2} is each independently C₁₋₆ alkyl, C₁₋₆ alkoxy or C₆₋₁₂ aryl, and

nc2 is each independently 0, 1, 2 or 3.

R^{c2} is preferably alkyl having a C₄₋₆ branched structure. Each R^{c2} in the formula can be identical or different, and is more preferably identical. R^{c2} is further preferably t-butyl or 1,1-dimethylpropyl, and still more preferably t-butyl.

nc2 is each preferably 1.

Exemplified examples of the formula (CC2) are as shown below:

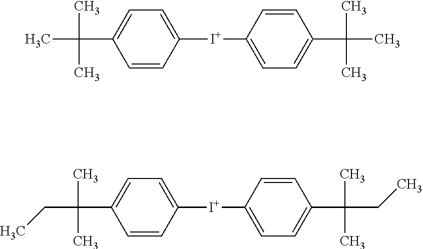

The formula (CA) is as shown below:

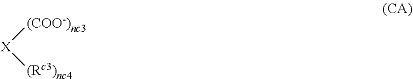

wherein,
X is a C₁₋₂₀ hydrocarbon group,
R^{c3} is each independently hydroxy, C₁₋₆ alkyl or C₆₋₁₀ aryl,
nc3 is 1, 2 or 3, and
nc4 is 0, 1 or 2.

X can be either of linear, branched or cyclic, but is preferably linear or cyclic. In the case of linear, it is preferably C₁₋₄ (more preferably C₁₋₂), and preferably has one double bond in the chain or is saturated. When it is cyclic, it can be a monocyclic aromatic ring, or a saturated monocyclic or polycyclic ring. When it is monocyclic, it is preferably a 6-membered ring, and when it is polycyclic, an adamantane ring is preferred.

X is preferably methyl, ethyl, propyl, butyl, ethane, phenyl, cyclohexane or adamantane, more preferably methyl, phenyl or cyclohexane, and further preferably phenyl.

nc3 is preferably 1 or 2, and more preferably 1.

nc4 is preferably 0 or 1, and more preferably 1.

R^{c3} is preferably hydroxy, methyl, ethyl, 1-propyl, 2-propyl, t-butyl or phenyl, and more preferably hydroxy.

Exemplified examples of the formula (CA) are as shown below:

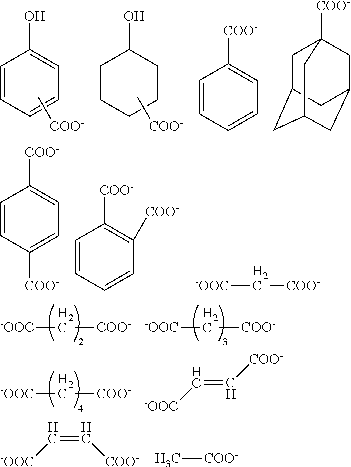

The molecular weight of the photoreaction quencher (C) is preferably 300 to 1,400, and more preferably 300 to 1,200.

The content of the photoreaction quencher (C) is preferably 0.01 to 3 mass %, and more preferably 0.02 to 1 mass %, based on the total mass of the polymer (A).

(D) Solvent

The composition according to the present invention comprises a solvent (D). The solvent is not particularly limited so far as it can dissolve each component blended. The solvent (D) is preferably water, a hydrocarbon solvent, an ether solvent, an ester solvent, an alcohol solvent, a ketone solvent, or any combination of any of these.

Exemplified examples of the solvent include water, n-pentane, i-pentane, n-hexane, i-hexane, n-heptane, i-heptane, 2,2,4-trimethylpentane, n-octane, i-octane, cyclohexane, methylcyclohexane, benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amyl naphthalene, trimethyl benzene, methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethyl nonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethyl carbinol, diacetone alcohol, cresol, ethylene glycol, propylene glycol, 1,3-butylene glycol, pentanediol-2,4,2-methylpentanediol-2,4, hexanediol-2,5, heptanediol-2,4,2-ethylhexanediol-1,3, diethylene glycol, dipropylene glycol, triethylene glycol, tripropylene glycol, glycerin, acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-i-butyl ketone, trimethylnonane, cyclohexanone, cyclopentanone, methylcyclohexanone, 2,4-pentanedione, acetonylacetone, diacetone alcohol, acetophenone, fenthion, ethyl ether, i-propyl ether, n-butyl ether (dibutyl ether, DBE), n-hexyl ether, 2-ethylhexyl ether, ethylene oxide, 1,2-propylene oxide, dioxolane, 4-methyl dioxolane, dioxane, dimethyl dioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, 2-methyltetrahydrofuran, diethyl carbonate, methyl acetate, ethyl acetate, γ-butyrolactone, γ-valerolactone, n-propyl acetate, i-propyl acetate, n-butyl acetate (normal butyl acetate, nBA), i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methyl cyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate (EL), γ-butyrolactone, n-butyl lactate, n-amyl lactate, diethyl malonate, dimethyl phthalate, diethyl phthalate, propylene glycol 1-monomethyl ether 2-acetate (PGMEA), propylene glycol monoethyl ether acetate, propylene glycol monopropyl ether acetate, N-methylformamide, N,N-dimethylformamide, N,N-diethylformamide, acetamide, N-methylacetamide, N,N-dimethylacetamide, N-methylpropionamide, N-methyl pyrrolidone, dimethyl sulfide, diethyl sulfide, thiophene, tetrahydrothiophene, dimethyl sulfoxide, sulfolane, and 1,3-propane sultone. These solvents can be used alone or in any combination of any two or more of these.

The solvent (D) is preferably PGME, PGMEA, EL, nBA, DBE or any combination of any of these, and more preferably PGME, EL, nBA, DBE or any combination of any of these. It is also another embodiment of the present invention that the solvent (D) is PGME, PGMEA or a mixture thereof. When the two types are mixed, the mass ratio of the first solvent to the second solvent is preferably 95:5 to 5:95 (more preferably 90:10 to 10:90, and further preferably 80:20 to 20:80). When the three types are mixed, the mass ratio of the first solvent to the sum of the three types is 30 to 90% (more preferably 50 to 80%, and further preferably 60 to 70%), the mass ratio of the second solvent to the sum of the three types is 10 to 50% (more preferably 20 to 40%), and the mass ratio of the third solvent to the sum of the three types is 5 to 40% (more preferably 5 to 20%, and further preferably 5 to 15%).

In relation to other layers or films, it is also one aspect that the solvent (D) substantially contains no water. For example, the amount of water in the total solvent (D) is preferably 0.1 mass % or less, more preferably 0.01 mass % or less, and further preferably 0.001 mass % or less. It is also a preferable embodiment that the solvent (D) contains no water (0 mass %).

The content of the solvent (D) is 30 to 90 mass %, more preferably 30 to 85 mass %, and further preferably 50 to 85 mass %, based on the total mass of the composition. The film thickness after film formation can be controlled by increasing or decreasing the amount of the solvent in the entire composition.

(E) Basic Compound

The composition according to the present invention can further comprise a basic compound (E). The basic compound has an effect of suppressing the diffusion of the acid generated in the exposed area and an effect of suppressing the deactivation of the acid on the resist film surface by the amine component contained in the air. In addition, in the composition according to the present invention, as described above, since the photoreaction quencher (C) has these effects, the basic compound (E) is not essential in the present invention.

The basic compound (E) includes ammonia, C₁₋₁₆ primary aliphatic amine, C₂₋₃₂ secondary aliphatic amine, C₃₋₄₈ tertiary aliphatic amine, C₆₋₃₀ aromatic amine, C₅₋₃₀ heterocyclic amine, and derivatives thereof.

Exemplified examples of the basic compound (E) include ammonia, ethylamine, n-octylamine, n-heptylamine, ethylenediamine, triethylamine, tri-n-octylamine, diethylamine, tris[2-(2-methoxyethoxy)ethyl]amine, 1,8-diazabicyclo[5.4.0]undecene-7, 1,5-diazabicyclo[4.3.0]nonene-5, 7-methyl-1,5,7-triazabicyclo[4.4.0]dec-5-ene, and 1,5,7-triazabicyclo[4.4.0]dec-5-ene.

The base dissociation constant pKb (H₂O) of the basic compound (E) is preferably −12 to 5, and more preferably 1 to 4.

The molecular weight of the basic compound (E) is preferably 17 to 500, and more preferably 60 to 400.

The content of the basic compound (E) is preferably 0 to 2 mass %, and more preferably 0 to 1 mass %, based on the total mass of the polymer (A). In consideration of storage stability of the composition, it is also a preferable embodiment to contain no basic compound (E).

(F) Plasticizer

The composition according to the present invention can further comprise a plasticizer (F). By adding a plasticizer, film cracking in the case of a thick film can be suppressed.

Examples of the plasticizer include alkali-soluble vinyl polymer and acid-dissociable group-containing vinyl polymer. For example, polyvinyl chloride, polystyrene, polyhydroxystyrene, polyvinyl acetate, polyvinyl benzoate, polyvinyl ether, polyvinyl butyral, polyvinyl alcohol, polyether ester, polyvinyl pyrrolidone, polyacrylic acid, polymethacrylic acid, polyacrylic ester, maleic acid polyimide, polyacrylamide, polyacrylonitriles polyvinylphenol, novolac and copolymer thereof are included, and polyvinyl ether, polyvinyl butyral and polyether ester are more preferable.

Exemplified examples of the plasticizer (F) are as shown below:

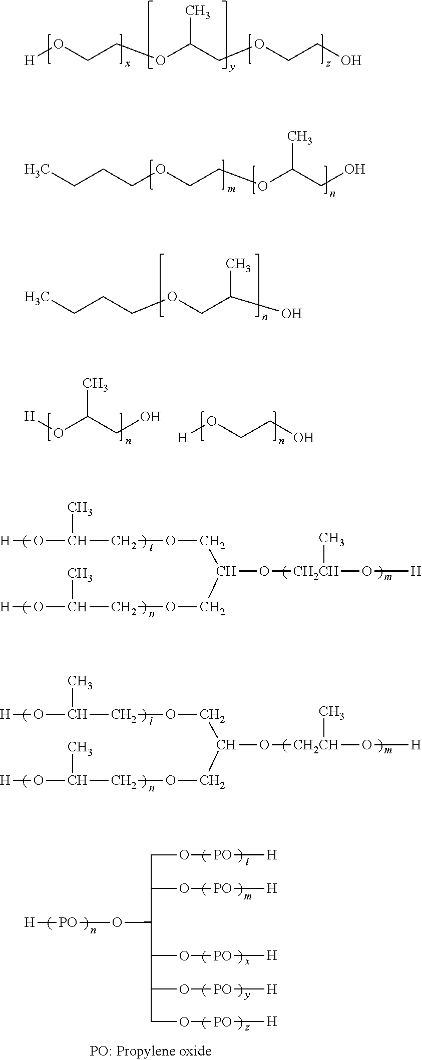

The mass average molecular weight of the plasticizer (F) is preferably 1,000 to 50,000, more preferably 1,500 to 30,000, further preferably 2,000 to 21,000, and still more preferably 2,000 to 15,000.

The content of the plasticizer (F) is preferably 0 to 20 mass %, and more preferably 0 to 17 mass %, based on the total mass of the (A) polymer. It is also a preferable aspect of the present invention to contain no plasticizer.

(G) Additive

The composition according to the present invention can comprise other additive (G) than (A) to (F).

The additive (G) is not particularly limited, but is preferably at least one selected from the group consisting of surfactants, dyes, contrast enhancers, acids and substrate adhesion enhancers.

The content of the additive (G) is 0 to 20 mass %, and more preferably 0 to 11 mass %, based on the total mass of the polymer (A). It is also a preferable example of the composition according to the present invention to contain no additive (G) (0 mass %).

By including a surfactant, coating properties can be improved. As the surfactant that can be used in the present invention, (I) an anionic surfactant, (II) a cationic surfactant or (III) a nonionic surfactant are included, and for example, (I) alkyl sulfonate, alkylbenzene sulfonic acid and alkylbenzene sulfonate, (II) lauryl pyridinium chloride and lauryl methyl ammonium chloride, and (III) polyoxyethylene octyl ether, polyoxyethylene lauryl ether, polyoxy ethylene acetylenic glycol ether, fluorine-containing surfactants (for example, Fluorad (3M), Megafac (DIC), Surflon (AGC)), and organosiloxane surfactants (for example, KF-53, KP341 (Shin-Etsu Chemical)) are included.

These surfactants can be used alone or in any combination of any two or more of them, and the content thereof is preferably 2 mass % or less, and more preferably 1 mass % or less, based on the total mass of the polymer (A).

By including a dye, pattern shape can be improved. The dye is not particularly limited so far as it is a compound having an appropriate absorption at the exposure wavelength. Examples thereof include benzene, naphthalene, anthracene, phenanthrene, pyrene, isocyanuric acid, triazine, and derivatives thereof.

Examples of the contrast enhancer include a low molecular weight compound derived from an alkali-soluble phenolic compound or a hydroxycyclic compound, which includes an acid-labile group (hereinafter referred to as the leaving group). Here, the leaving group reacts with the acid released from the deprotecting agent and leaves from the compound, and solubility of the compound in the alkaline aqueous solution becomes higher, thereby increasing contrast. Such a leaving group is, for example, —R^{r1}, —COOR^{r1} or —R^{r2}—COOR^{r1} (wherein, R^{r1} is a linear, branched or cyclic alkyl group having 1 to 10 carbon atoms, which can contain an oxygen atom between carbon-carbon, and R^{r2} is an alkylene group having 1 to 10 carbon atoms), and can be replaced with hydrogen in a hydroxyl group bonded to the compound. Such a contrast enhancer preferably contains two or more of leaving groups in the molecule. Further, the mass average molecular weight thereof is 3,000 or less, and preferably 100 to 2,000. Preferred compounds before introducing a leaving group into the hydroxyl group are as shown below:

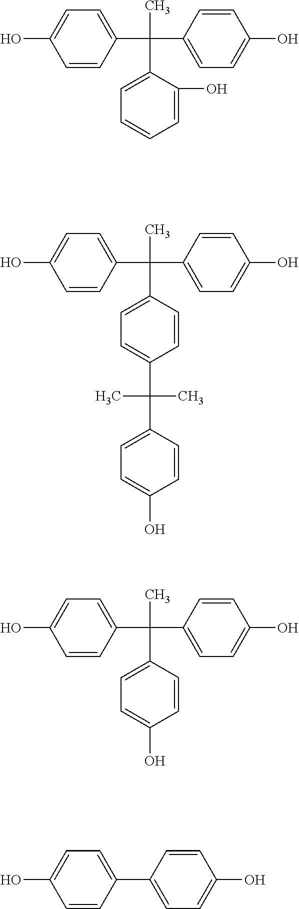 [SMILES: CC(c1ccc(O)cc1)(c1ccc(O)cc1)c1ccccc1O ; CC(C)(c1ccc(O)cc1)c1ccc(C(C)(c2ccc(O)cc2)c2ccc(O)cc2)cc1 ; CC(c1ccc(O)cc1)(c1ccc(O)cc1)c1ccc(O)cc1 ; Oc1ccc(-c2ccc(O)cc2)cc1]

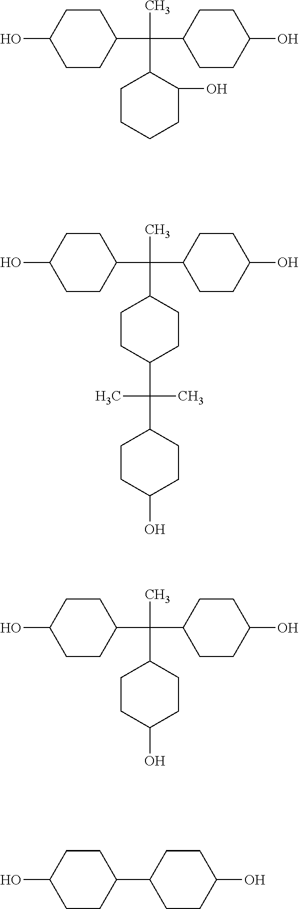 [SMILES: CC(C1CCC(O)CC1)(C1CCC(O)CC1)C1CCCCC1O ; CC(C)(C1CCC(O)CC1)C1CCC(C(C)(C2CCC(O)CC2)C2CCC(O)CC2)CC1 ; CC(C1CCC(O)CC1)(C1CCC(O)CC1)C1CCC(O)CC1 ; OC1CCC(C2CCC(O)CC2)CC1]

These contrast enhancers can be used alone or in any combination of any two or more of these, and the content thereof is preferably 0.5 to 40 mass %, and more preferably 1 to 20 mass %, based on the total mass of the polymer (A).

The acid can be used to adjust pH value of the composition and improve solubility of the additive component. The acid to be used is not particularly limited, but examples thereof include formic acid, acetic acid, propionic acid, benzoic acid, phthalic acid, salicylic acid, lactic acid, malic acid, citric acid, oxalic acid, malonic acid, succinic acid, fumaric acid, maleic acid, aconitic acid, glutaric acid, adipic acid, and any combination of any of these. The content of the acid is preferably 0.005 mass % or more and 0.1 mass % or less (50 ppm to 1,000 ppm) based on the total mass of the composition.

Using the substrate adhesion enhancer, it is possible to prevent the pattern from being peeled off due to the stress applied during film formation. As the substrate adhesion enhancer, imidazoles and silane coupling agents are preferable. Among imidazoles, 2-hydroxybenzimidazole, 2-hydroxyethylbenzimidazole, benzimidazole, 2-hydroxyimidazole, imidazole, 2-mercaptoimidazole and 2-aminoimidazole are preferred, and 2-hydroxybenzimidazole, benzimidazole, 2-hydroxyimidazole and imidazole are more preferably used. The content of the substrate adhesion enhancer is preferably 0 to 2 mass %, and more preferably 0 to 1 mass %, based on the total mass of the polymer (A).

<Method for Manufacturing Resist Film>

The method for manufacturing a resist film according to the present invention comprises the following processes:

(1) applying the composition according to the present invention above a substrate; and

(2) heating the composition to form a resist film.

Hereinafter, one aspect of the manufacturing method according to the present invention is described.

The composition according to the present invention is applied above a substrate (for example, a silicon/silicon dioxide-coated substrate, a silicon nitride substrate, a silicon wafer substrate, a glass substrate, an ITO substrate, and the like) by an appropriate method. Here, in the present invention, the “above” includes the case where a layer is formed in contact with and above a substrate and the case where a layer is formed above a substrate with another layer in contact with the layer. For example, a planarization film or resist underlayer can be formed in contact with and above a substrate, and the composition according to the present invention can be applied contact with and above the film. The application method is not particularly limited, but for example, a method using a spinner or a coater is included. After application, the film according to the present invention is formed by heating. The heating of (2) is performed, for example, by a hot plate. The heating temperature is preferably 100 to 250° C., more preferably 100 to 200° C., and further preferably 100 to 160° C. The temperature here is a temperature of heating atmosphere, for example, that of a heating surface of a hot plate. The heating time is preferably 60 to 300 seconds, and more preferably 60 to 240 seconds. The heating is preferably performed in the air or a nitrogen gas atmosphere.

The film thickness of the resist film is selected depending on the purpose, but when the composition according to the present invention is used, a pattern having a better shape can be formed when a thick coating film is formed. For this reason, it is preferable that the thickness of the resist film is thicker, for example, preferably 1 μm or more, and more preferably 1.5 μm or more. In addition, the upper limit is not particularly limited, but it is preferably 25 μm or less, and more preferably 20 μm or less, from the viewpoint of productivity or the like.

A resist pattern can be manufactured by the method further comprising the following processes:

(3) exposing the resist film; and

(4) developing the resist film.

For the sake of clarity it is noted that, the processes (1) and (2) are performed before the process (3). The numbers in parentheses mean the order. This is the same hereinafter as well.

The resist film is exposed through a predetermined mask. The wavelength of light to be used for exposure is not particularly limited, but the exposure is preferably performed with light having a wavelength of 13.5 to 248 nm. For example, KrF excimer laser (wavelength: 248 nm), ArF excimer laser (wavelength: 193 nm), extreme ultraviolet light (wavelength: 13.5 nm) and the like can be used. KrF excimer laser is preferred. These wavelengths accept a range of ±1%. After exposure, post exposure bake (PEB) can be performed as necessary. The temperature of post exposure bake is preferably 80 to 150° C., more preferably 100 to 140° C., and the baking time is 0.3 to 5 minutes, preferably 0.5 to 2 minutes.

The exposed resist film is subjected to development using a developer. As the developing method, a method conventionally used for developing a photoresist, such as a paddle developing method, an immersion developing method, or a swinging immersion developing method, can be used. Further, as the developer, aqueous solution containing inorganic alkalis, such as sodium hydroxide, potassium hydroxide, sodium carbonate and sodium silicate; organic amines, such as ammonia, ethylamine, propylamine, diethylamine, diethylaminoethanol and triethylamine; quaternary amines, such as tetramethylammonium hydroxide (TMAH); and the like are used, and a 2.38 mass % TMAH aqueous solution is preferred. To the developer, a surfactant can be further added. The temperature of the developer is preferably 5 to 50° C., more preferably 25 to 40° C., and the developing time is preferably 10 to 300 seconds, more preferably 30 to 60 seconds. After development, washing or rinsing can also be performed as necessary. When a positive type resist composition is used, the exposed area is removed by development to form a resist pattern. The resist pattern can also be further made finer, for example, using a shrink material.

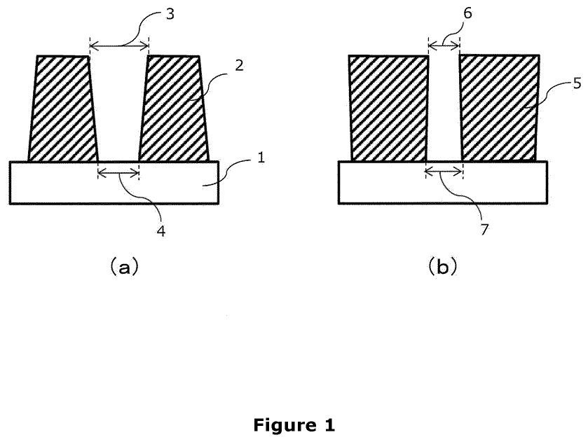

It is a known phenomenon that when the resist pattern is formed using a chemically amplified resist, the shape of a resist pattern changes if the time left standing from exposure to post exposure bake (PED: Post Exposure Delay) becomes longer. For example, FIG. 1(a) shows an example of the resist pattern when PED=1 minute. The resist pattern (2) is formed on the substrate (1). At this time, the width at the top part between the resist pattern walls (that is, the space portion) is referred to as ITW (3) and the width at the bottom part thereof is referred to as IBW (4). In this case, ITW>IBW. FIG. 1(b) shows an example of the resist pattern when PED=30 minute. At this time, the width at the top part between the resist pattern walls (that is, the space portion) is referred to as FTW (6) and the width at the bottom part thereof is referred to as FBW (7).

This phenomenon is considered to be caused by the fact that the acid generated in the exposed area of the resist is neutralized by a basic compound (for example, amine component) in the air, and the solubility of the resist film surface of the exposed area is lowered. The top part of the resist film is easily affected by this, and the resist pattern, a part of which in the exposed area of the top part remains undeveloped, is also called a T shape. As described above, a resist pattern obtained with a long PED and affected by the environment tends to have a narrower trench width compared with a resist pattern obtained with a short PED. In other words, the trench width is not so narrowed in the resist film that is robust against environmental impact.

The composition according to the present invention comprises, as described above, the photoreaction quencher (C) and is considered to be robust against environmental impact.

Preferably, ITW−FTW≤400 nm (more preferably 390 nm, and further preferably ≤320 nm); and/or

preferably IBW−FBW≤50 nm (more preferably 48 nm, and further preferably ≤45 nm).

Further, the conditions for comparing these numerical values are preferably measured in conformity with the examples described later as much as possible. For example, it is preferable to form a film having a thickness of 4.3 μm and then to form a resist pattern.

The manufacturing environment of the resist pattern requires a manufacturing level condition. For example, a clean room cleanliness management level described in Non-Patent Document 1 is required. As described above, since the basic compound in the air changes solubility of the resist film surface, an environment with extremely low cleanliness cannot sufficiently bring out the performance of the composition of the present invention. For example, the cleanliness is managed to make it 3.5 μg/m³ or less for the basic compound (ammonia etc.).

Even if PED occurs in the manufacturing process, it is considered that the composition according to the present invention has an advantageous effect capable of reducing the environmental impact.

A processed substrate can be manufactured by the method further comprising the following process:

(5) processing with the resist pattern as a mask.

The formed resist pattern is preferably used for processing a underlayer or a substrate (more preferably the substrate). For example, with the resist pattern as a mask, various substrates that is a underlying material can be processed using a dry etching method, a wet etching method, an ion implantation method, a metal plating method, or the like. The resist pattern according to the present invention is preferably used for substrate processing using an ion implantation method because it can increase the film thickness and the aspect ratio. That is, when impurity doping is performed by ion implantation using the resist pattern as a mask, only the area of the substrate that is not covered with the resist pattern is doped. In this way, by doping impurities only in a desired area, a smaller semiconductor device structure or the like can be formed on the substrate.

When processing an underlayer using a resist pattern, the processing can be performed in stages. For example, a BARC can be processed using a resist pattern, a SOC film can be processed using the BARC pattern, and a substrate can be processed using the SOC pattern.

Wiring can also be formed in a gap formed by processing the substrate.

Thereafter, if necessary, the substrate is further processed to form a device. For these further processing, known methods can be applied. After forming the device, if necessary, the substrate is cut into chips, which are connected to a lead frame and packaged with resin. In the present invention, this packaged product is referred to as the device. Examples of the device include a semiconductor device, a liquid crystal display device, an organic EL display device, a plasma display device, and a solar cell device. The device is preferably a semiconductor.

### EXAMPLES

The present invention is described below with reference to various examples. In addition, the aspect of the present invention is not limited only to these examples.

Preparation of Composition 1

In order to obtain a thick resist film of 4.3 μm, Composition 1 is prepared as follows. 100 mass part of the polymer (A1) is added to 275 mass part of a mixed solvent having a mass ratio of PGME:EL=70:30. To this, 1.7 mass % of the deprotecting agent (B1), 0.1 mass % of the photoreaction quencher (C1) and 0.1 mass % of the surfactant KF-53 (Shin-Etsu Chemical), based on the total mass of the polymer (A1), are respectively added. This is stirred at room temperature for 30 minutes. It is visually confirmed that the additives are dissolved. This is filtered through a 0.05 μm filter. Thereby, Composition 1 is obtained.

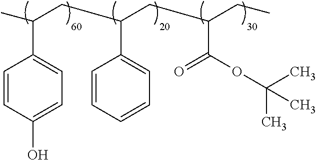

(A1) Hydroxystyrene:styrene:t-butyl acrylate copolymer, Maruzen Petrochemical, 60:20:20 respectively in molar ratio, Mw: about 12,000

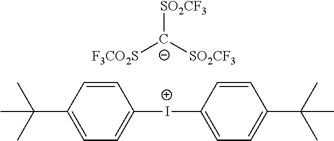

### (B1) DTBPIO-C1, Heraeus

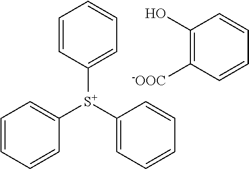

### (C1) Toyo Gosei

Preparation of Compositions 2 to 12 and Comparative Compositions 1 and 2

Compositions 2 to 12 and Comparative Compositions 1 and 2 are obtained in the same manner as the preparation of Composition 1 except that the compositions are changed as shown in Table 1.

Preparation of Comparative Composition 3

In order to obtain a thin resist film of 0.76 μm, Comparative Composition 3 is prepared as follows.

100 mass part of the polymer (A1) is added to 746 mass part of a mixed solvent having a mass ratio of PGME:EL=70:30. To this, 1.7 mass % of the deprotecting agent (B1), 0.1 mass % of the photoreaction quencher (C1) and 0.1 mass % of the surfactant KF-53 (Shin-Etsu Chemical), based on the total mass of the polymer (A1), are respectively added. This is stirred at room temperature for 30 minutes. It is visually confirmed that the additives are dissolved. This is filtered through a 0.05 μm filter. Thereby, Comparative Composition 3 is obtained.

Preparation of Comparative Compositions 4 to 7

Comparative Compositions 4 to 7 are obtained in the same manner as the preparation of Comparative Composition 3 except that the compositions are changed as shown in Table 1.

Formation of Resist Film

A resist film is obtained by performing the following operation using the compositions obtained above.

Each composition is dropped on an 8-inch silicon wafer and spin-coated, using a coater Mark 8 (Tokyo Electron). The wafer is baked on a hot plate at 150° C. for 130 seconds. Resist films respectively of 4.3 μm and 0.76 μm are obtained using the compositions respectively for thick film and thin film. The film thickness is measured using a spectroscopic film thickness measurement system M-1210 (SCREEN). In addition, the film thickness is measured at 8 points on the wafer excluding the central part, and the average value thereof is used.

Example of Resist Pattern Formation

The resist film formed in the above example of resist film formation is exposed using a KrF stepper (FPA 300-EXS, Canon). The wafer is subjected to PEB on a hot plate at 110° C. for 160 seconds. At this time, the time from exposure to PEB (that is, PED) is 1 minute. This is subjected to paddle development for 60 seconds with a developer AZ300MIF (2.38% TMAH aqueous solution, Merck Performance Materials (hereinafter referred to as MPM)). Thereby, a resist pattern of Line=1700 nm and Space (trench)=340 nm (Line:Space=5:1) is obtained. In addition, although the trench width at the bottom part between the pattern walls (corresponding to 4 in FIG. 1(a)) is 340 nm, the width at the top part between the pattern walls is widened, and the pattern wall sometimes become a tapered shape.

The exposure energy (mJ/cm²) when the ratio of the mask size to the pattern size become 1:1 is defined as the sensitivity. The results are shown in Table 1 below.

The sensitivity evaluation criteria are as follows:

### Sensitivity Under the Conditions of a Thick Film (4.3 μm):

X: ≤200 mJ/cm²

Y: >200 mJ/cm², ≤350 mJ/cm²

Z: >350 mJ/cm²

### Sensitivity Under the Conditions of a Thin Film (0.76 μm):

X: ≤100 mJ/cm²

Y: >100 mJ/cm², ≤200 mJ/cm²

Z: >200 mJ/cm²

Resolution Measurement

A mask pattern of Line:Space=5:1, in which the space width gradually decreases by 20 nm from 340 nm, is used. The exposure is performed with an exposure amount at which a 340 nm slit can reproduce a 340 nm pattern. A stepper FPA-3000EX5 (Canon) is used. The sectional SEM is used to confirm the pattern shape sequentially from the 340 nm pattern. The space width in the pattern just before the space is crushed is defined as the resolution.

The results are shown in Table 1 below.

The resolution evaluation criteria are as follows.

### Resolution Under the Conditions of a Thick Film

X: ≤300 nm

Y: >300 nm, ≤340 nm

Z: >340 nm

### Resolution Under the Conditions of a Thin Film

X: ≤260 nm

Y: >260 nm

TABLE 1

| | | | | | | Film | | | | |
|---|---|---|---|---|---|---|---|---|---|---|
| | | Composition | | | | thickness | Sensitivity | | Resolution | |
| | | (A) | (B) | (C) | (E) | (μm) | (mJ/cm²) | | (nm) | |
| Example | Composition 1 | A1 | B1(1.7) | C1(0.1) | — | 4.3 | 46 | X | 300 | X |
| | Composition 2 | A1 | B1(1.7) | C1(0.2) | — | 4.3 | 66 | X | 300 | X |
| | Composition 3 | A1 | B1(1.7) | C1(0.3) | — | 4.3 | 86 | X | 300 | X |
| | Composition 4 | A1 | B1(1.7) | C1(0.5) | — | 4.3 | 144 | X | 300 | X |
| | Composition 5 | A1 | B1(1.7) | C1(1.0) | — | 4.3 | 340 | Y | 300 | X |
| | Composition 6 | A1 | B1(1.7) | C1(0.1) | E1(0.1) | 4.3 | 66 | X | 300 | X |
| | Composition 7 | A1 | B1(1.7) | C1(0.225) | E1(0.075) | 4.3 | 90 | X | 280 | X |
| | Composition 8 | A1 | B1(1.7) | C1(0.15) | E1(0.15) | 4.3 | 90 | X | 300 | X |
| | Composition 9 | A1 | B1(1.7) | C1(0.075) | E1(0.225) | 4.3 | 90 | X | 320 | Y |
| | Composition 10 | A1 | B1(1.7) | C1(0.375) | E1(0.125) | 4.3 | 152 | X | 280 | X |
| | Composition 11 | A1 | B1(1.7) | C1(0.25) | E1(0.25) | 4.3 | 164 | X | 300 | X |
| | Composition 12 | A1 | B1(1.7) | C1(0.125) | E1(0.375) | 4.3 | 206 | Y | 320 | Y |
| Comparative | Comparative | A1 | B1(1.7) | — | E1(0.3) | 4.3 | 94 | X | 320 | Y |
| Example | Composition 1 | | | | | | | | | |
| | Comparative | A1 | B1(1.7) | — | E1(0.5) | 4.3 | 370 | Z | 320 | Y |
| | Composition 2 | | | | | | | | | |
| | Comparative | A1 | B1(1.7) | — | E1(0.1) | 0.76 | 21 | X | 280 | Y |
| | Composition 3 | | | | | | | | | |
| | Comparative | A1 | B1(1.7) | — | E1(0.5) | 0.76 | 225 | Z | 280 | Y |
| | Composition 4 | | | | | | | | | |
| | Comparative | A1 | B1(1.7) | C1(0.1) | — | 0.76 | 19 | X | 280 | Y |
| | Composition 5 | | | | | | | | | |
| | Comparative | A1 | B1(1.7) | C1(0.225) | E1(0.075) | 0.76 | 34 | X | 260 | X |
| | Composition 6 | | | | | | | | | |
| | Comparative | A1 | B1(1.7) | C1(0.075) | E1(0.225) | 0.76 | 42 | X | 260 | X |
| | Composition 7 | | | | | | | | | |

In the above table, (A) represents polymer, (B) represents a deprotecting agent, (C) represents a photoreaction quencher, and (E) represents a basic compound. In the above table, the numbers in parentheses in the columns (B), (C) and (E) are mass % based on the total mass of the polymer (A). The same applies to the following tables.

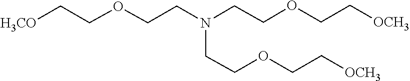 [SMILES: COCCOCCN(CCOCCOC)CCOCCOC]

### (Base E1) 301248, Sigma-Aldrich

As shown in the above table, it can be confirmed that each composition comprising the photoreaction quencher of the present invention has sensitivity and resolution suitable as a thick film resist. Moreover, it can be confirmed that even if these are used as a thin film resist, these have suitable sensitivity and resolution.

PED Evaluation Test

Using the compositions described in Table 2 below, environmental impact is evaluated as follows.

Example of resist pattern measurement

The shape of the resist pattern prepared in the above example of resist pattern formation is confirmed using a scanning electron microscope (SEM). The width of the pattern surface is measured.

The width between the pattern walls at the top part is referred to as ITW (nm) and the width between the pattern walls at the bottom part is referred to as IBW (nm).

Formation and measurement of resist patterns exposed to clean room air

Using the compositions obtained in the preparation examples, the following operation is performed to obtain resist films.

A resist film formed in accordance with the above example of resist film formation is exposed using a KrF stepper (FPA 3000-EX5). The same exposure energy as that used in the above example of resist pattern formation is used for each of composition and film thickness.

The wafer is taken out from the KrF stepper and left to stand on the laboratory table (in the clean room) for 30 minutes (that is, PED=30 minutes). The wafer is subjected to PEB on a hot plate at 110° C. for 160 seconds. This is subjected to paddle development for 60 seconds with a developer AZ300MIF. Thereby, a resist pattern affected by the environment is obtained. The shape of the resulting resist pattern is confirmed using SEM, and the width of the pattern surface is measured.

The width between the pattern walls at the top part is referred to as FTW (nm) and the width between the pattern walls at the bottom part is referred to as FBW (nm).

The environmental impact is calculated and evaluated as follows.

TG(nm)=ITW−FTW

BG(nm)=IBW−FBW

The TG evaluation criteria are as follows.

### TG Under the Conditions of a Thick Film

X: ≤400 nm

Y: >400 nm, the top part is connected and the trench disappears.

### TG Under the Conditions of a Thin Film

X: ≤150 nm

Y: >150 nm, the top parts are connected and the trench disappears.

The BG evaluation criteria are as follows.

### BG Under the Conditions of a Thick Film

X: ≤50 nm

Y: >50 nm

Z: The bottom parts are connected and the trench disappears.

### BG Under the Conditions of a Thin Film

X: ≤40 nm

Y: >40 nm

Z: The bottom parts are connected and the trench disappears.

TABLE 2

| | | | | | | Film | | | | |
|---|---|---|---|---|---|---|---|---|---|---|
| | | Composition | | | | thickness | TG | | BG | |
| | | (A) | (B) | (C) | (E) | (μm) | (nm) | | (nm) | |
| Example | Composition 2 | A1 | B1(1.7) | C1(0.2) | — | 4.3 | 318 | X | 40 | X |
| | Composition 3 | A1 | B1(1.7) | C1(0.3) | — | 4.3 | 377 | X | 46 | X |
| | Composition 4 | A1 | B1(1.7) | C1(0.5) | — | 4.3 | 332 | X | 33 | X |
| | Composition 5 | A1 | B1(1.7) | C1(1.0) | — | 4.3 | 277 | X | 46 | X |
| | Composition 6 | A1 | B1(1.7) | C1(0.1) | E1(0.1) | 4.3 | 285 | X | 20 | X |
| | Composition 10 | A1 | B1(1.7) | C1(0.375) | E1(0.125) | 4.3 | 325 | X | 0 | X |
| | Composition 12 | A1 | B1(1.7) | C1(0.125) | E1(0.375) | 4.3 | 384 | X | 19 | X |
| Comparative | Comparative | A1 | B1(1.7) | — | E1(0.3) | 4.3 | 549 | Y | Trench | Z |
| Example | Composition 1 | | | | | | | | disappears | |
| | Comparative | A1 | B1(1.7) | — | E1(0.5) | 4.3 | Trench | Z | Trench | Z |
| | Composition 2 | | | | | | disappears | | disappears | |
| | Comparative | A1 | B1(1.7) | — | E1(0.1) | 0.76 | 178 | Y | 16 | X |
| | Composition 3 | | | | | | | | | |
| | Comparative | A1 | B1(1.7) | C1(0.1) | — | 0.76 | 207 | Y | 31 | X |
| | Composition 5 | | | | | | | | | |
| | Comparative | A1 | B1(1.7) | C1(0.225) | E1(0.075) | 0.76 | 167 | Y | 20 | X |
| | Composition 6 | | | | | | | | | |
| | Comparative | A1 | B1(1.7) | C1(0.075) | E1(0.225) | 0.76 | 155 | Y | 16 | X |
| | Composition 7 | | | | | | | | | |

As shown in the above table, it can be confirmed that each composition comprising the photoreaction quencher of the present invention is less affected by the environment than the comparative compositions when used as a thick film resist. Furthermore, when used as a thick film resist, an effect of reducing the environment impact can be expected more than when used as a thin film resist.

Preparation of Reference Composition 1

In order to obtain a thick resist film of 4.3 μm, Reference Composition 1 is prepared as follows.

100 mass part of the polymer (A1) is added to 275 mass part of a mixed solvent having a mass ratio of PGME:EL=70:30. To this, 0.5 mass % and 1.9 mass % respectively of the deprotecting agents (B2) and (B3), 0.2 mass % of the photoreaction quencher (C1) and 0.1 mass % of the surfactant KF-53 (Shin-Etsu Chemical), based on the total mass of the polymer (A1), are respectively added. This is stirred at room temperature for 30 minutes. It is visually confirmed that the additives are dissolved. This is filtered through a 0.05 μm filter. Thereby, Reference Composition 1 is obtained.

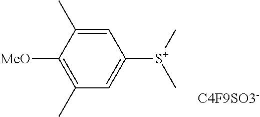

### (B2) ZK-0231, DSP Gokyo Food & Chemical Co., Ltd.

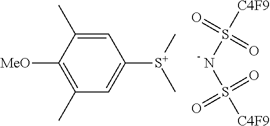

### (B3) ZK-1542, DSP Gokyo Food & Chemical Co., Ltd.

Preparation of Reference Composition 2

In order to obtain a thick resist film of 4.3 μm, Reference Composition 2 is prepared as follows.

100 mass part of the polymer (A1) is added to 275 mass part of a mixed solvent having a mass ratio of PGME:EL=70:30. To this, 0.5 mass % and 1.9 mass % respectively of the deprotecting agents (B2) and (B3), 0.1 mass % of the photoreaction quencher (C1), 0.1 mass % of base (E1) and 0.1 mass % of the surfactant KF-53 (Shin-Etsu Chemical), based on the total mass of the polymer (A1), are respectively added. This is stirred at room temperature for 30 minutes. It is visually confirmed that the additives are dissolved. This is filtered through a 0.05 μm filter. Thereby, Reference Composition 2 is obtained.

Comparison of Compositions 2 and 6 with Reference Compositions 1 and 2

Resist patterns are obtained respectively from Reference Compositions 1 and 2 in the same manner as in the above-described resist film formation example and resist pattern formation example. By the above-described methods, sensitivity, resolution and environmental impact are evaluated.

Sensitivity of Compositions 2 and 6 are equal to or higher than that of Reference Compositions 1 and 2. Resolution of Compositions 2 and 6 are slightly better than that of Reference Compositions 1 and 2. Environmental impact of Compositions 2 and 6 are equal to or more than that of Reference Compositions 1 and 2.

Preparation of Composition 20

In order to obtain a thick resist film of 7.0 μm, Composition 20 is prepared as follows.

100 mass part of the polymer (A2) is added to 198 mass part of a mixed solvent having a mass ratio of PGME:nBA:DBE=60:30:10. To this, 0.3 mass % of the deprotecting agent (B4), 0.05 mass % of the photoreaction quencher (C1), 2. 5 mass % of the plasticizer (F1) and 0.1 mass % of the surfactant KF-53 (Shin-Etsu Chemical), based on the total mass of the polymer (A2), are respectively added. This is stirred at room temperature for 30 minutes. It is visually confirmed that the additives are dissolved. This is filtered through a 0.05 μm filter. Thereby, Composition 20 is obtained.

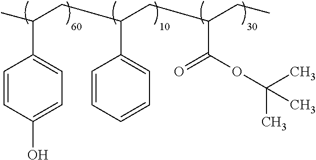

(A2) Hydroxystyrene:styrene:t-butyl acrylate copolymer, Toho Chemical Industries, 60:10:30 respectively in molar ratio, Mw: about 12,000

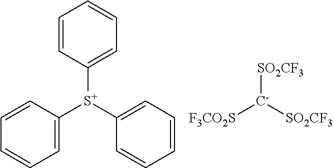

### (B4) TPS-C1, Heraeus K.K.

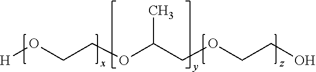

### (F1) Sanyo Chemical Industries, Ltd., SANNIX PL-2100

Example of Resist Film Formation

Composition 20 is dropped onto an 8-inch silicon wafer and spin-coated, using a coater Mark 8 (Tokyo Electron). The wafer is baked on a hot plate at 150° C. for 130 seconds. Thereby, a resist film of 7.0 μm is obtained. The film thickness is measured using a spectroscopic film thickness measurement system M-1210 (SCREEN).

Example of Resist Pattern Formation

The resist film formed in the above example of resist film formation is exposed using a KrF stepper (FPA 300-EXS, Canon). The wafer is subjected to PEB on a hot plate at 110° C. for 160 seconds. This is subjected to paddle development for 60 seconds with a developer AZ300MIF (2.38% TMAH aqueous solution, MPM). Thereby, a resist pattern of Line=1500 nm and Space (trench)=300 nm (Line:Space=5:1) is obtained. In addition, although the trench width at the bottom part between the pattern walls is 300 nm, the width at the top part between the pattern walls is widened, and the pattern wall sometimes become a tapered shape.

The exposure energy (mJ/cm²) to be used is defined as the sensitivity. Sensitivity is 82 mJ/cm².

Resolution Measurement

A mask pattern of Line:Space=5:1, in which the space width gradually decreases by 20 nm from 300 nm, is used. The exposure is performed with an exposure amount at which a 300 nm slit can reproduce a 300 nm pattern. A stepper FPA-3000EX5 (Canon) is used. The sectional SEM is used to confirm the pattern shape sequentially from the 300 nm pattern. The space width in the pattern just before the space is crushed is defined as the resolution. Resolution is 280 nm.

Preparation of Comparative Composition 8

In order to obtain a thick resist film of 10.5 μm, Comparative Composition 8 is prepared as follows. 100 mass part of the polymer (A3) is added to 177 mass part of a mixed solvent having a mass ratio of PGME:PGMEA=70:30. To this, 3.5 mass % of the deprotecting agent (B5), 2.8 mass % of the basic compound (E1) and 0.15 mass % of the surfactant KF-53, based on the total mass of the polymer (A3), are respectively added. This is stirred at room temperature for 30 minutes. It is visually confirmed that the additives are dissolved. This is filtered through a 0.05 μm filter. Thereby, Comparative Composition 8 is obtained.

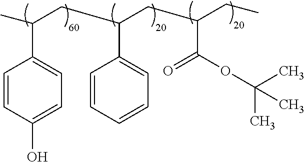

(A3) Hydroxystyrene:styrene:t-butyl acrylate copolymer, Toho Chemical Industry, 60:20:20 respectively in molar ratio, Mw: about 12,000

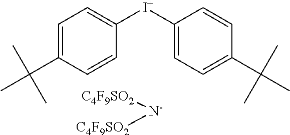

### (B5) ZK-0518, DSP Gokyo Food & Chemical Co., Ltd.

Preparation of Compositions 21 to 24

Compositions 21 to 24 are obtained in the same manner as the preparation of Comparative Composition 8 except that the compositions are changed as shown in Table 3. Here, in Table 3, the numbers in parentheses in the polymer (A) represents the mass ratio of each polymer. Those in (B), (C) and (E) are mass % based on the mass of the polymer (A) (the sum in the case of a plurality thereof).

Here, explanation is made with Composition 21. 100 mass part of a mixture having a mass ratio of the polymer (A4): the polymer (A5)=70:30 is added to 177 mass part of a mixed solvent having a mass ratio of PGME:PGMEA=70:30. To this, 1.7 mass % of the deprotecting agent (B4), 0.1 mass % of the photoreaction quencher (C1) and 0.15 mass % of the surfactant KF-53, based on the total mass of the polymer, are respectively added. No basic compound (E) is added. This is stirred at room temperature for 30 minutes. It is visually confirmed that the additives are dissolved. This is filtered through a 0.05 μm filter. Thereby, Composition 21 is obtained.

TABLE 3

| | | Composition | | | | | Etching |
|---|---|---|---|---|---|---|---|
| | | (A) | | (B) | (C) | (E) | (%) |
| Comparative | Comparative | A3(100) | — | B5(3.5) | — | E1(2.8) | 100 |
| Example | Composition 8 | | | | | | |
| Example | Composition 21 | A4(70) | A5(30) | B4(1.7) | C1(0.1) | — | 180 |
| | Composition 22 | A4(50) | A5(50) | B6(2.8) | C1(0.1) | — | 273 |
| | Composition 23 | A4(50) | A6(50) | B4(1.7) | C1(0.1) | — | 350 |
| | Composition 24 | A4(50) | A7(50) | B6(2.8) | C2(0.1) | — | 315 |

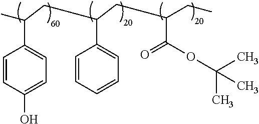

(A4) Hydroxystyrene:styrene:t-butyl acrylate copolymer, Toho Chemical Industry, 60:20:20
relatively in molar ratio, Mw: about 18,000 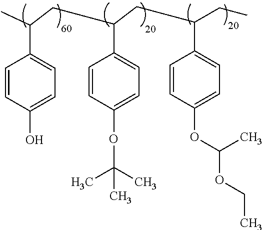
(A5) Hydroxystyrene:4-t-butoxystyrene:4-(1-ethoxyethoxy)styrene copolymer, Toho Chemical
Industry, 60:20:20 respectively in molar ratio, Mw: about 12,000 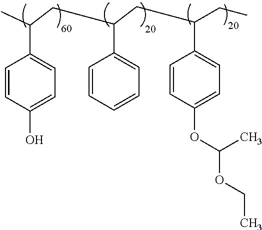
(A6) Hydroxystyrene:styrene:4-(1-ethoxyethoxy)styrene copolymer, Toho Chemical Industry,
60:20:20 respectively in molar ratio, Mw: about 12,000 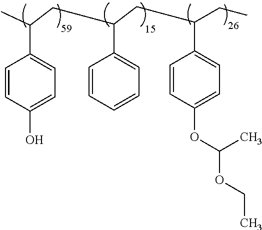
(A7) Hydroxystyrene:styrene:4-(1-ethoxyethoxy)styrene copolymer, Gunei Chemistry Industry,
59:15:26 respectively in molar ratio, Mw: about 12,000 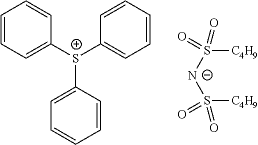
(B6) ZK-0517, DSP Gokyo Food & Chemical Co., Ltd. 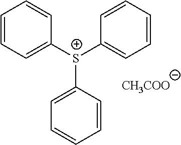
(C2) TPSA, Takemoto Oil & Fat

Formation of Resist Films of Comparative Composition 8 and Compositions 21 to 24

Each composition is dropped on an 8-inch silicon wafer and spin-coated, using a coater Mark 8 (Tokyo Electron). The wafer is baked on a hot plate at 140° C. for 90 seconds. Using each composition, each resist film of 10.5 μm is obtained. The film thickness is measured using a spectroscopic film thickness measurement system M-1210 (SCREEN). In addition, the film thickness is measured at 8 points on the wafer excluding the central part, and the average value thereof is used.

Evaluation of Etching Resistance

Dry etching is conducted using O₂ gas and CF₄ gas once each. The thickness of the film remaining after etching is measured using a spectroscopic film thickness measurement system M-1210. The film thickness is measured at 8 points on the wafer excluding the central part, and the average value thereof is used. The film thickness obtained with Comparative Composition 8 is treated as 100%, and the etching resistance of Compositions 21 to 24 is evaluated. The results are shown in Table 3. It is confirmed that the etching resistance of Compositions are higher than that of Comparative Composition 8.

### EXPLANATION OF SYMBOLS

1. substrate

2. resist pattern when PED is short

3. ITW

4. IBW

5. resist pattern when PED is long

6. FTW

7. FBW

1-16. (canceled)

17. A thick film resist composition comprising polymer (A), a deprotecting agent (B), a photoreaction quencher (C), and a solvent (D),
wherein the photoreaction quencher (C) is represented by the formula (C-1):
C^{m+}cation C^{m-}anion (C-1)
wherein,
C^{m+}cation consists of at least one cation selected from the group consisting of a cation represented by the formula (CC1) and a cation represented by the formula (CC2), and is m-valent as a whole, where m is 1 to 3: 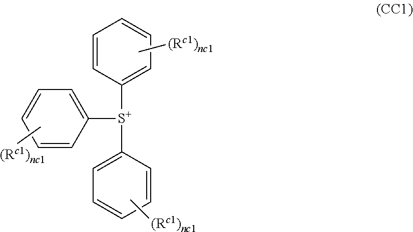
wherein,
R^{c1} each independently represents C₁₋₆ alkyl, C₁₋₆ alkoxy or C₆₋₁₂ aryl, and
nc1 is each independently 0, 1, 2, or 3, 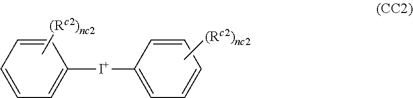
wherein,
R^{c2} is each independently C₁₋₆ alkyl, C₁₋₆ alkoxy or C₆₋₁₂ aryl, and
nc2 is each independently 0, 1, 2, or 3; and
C^{m-}anion consists of at least one anion selected from an anion represented by the formula (CA) and is m-valent as a whole: 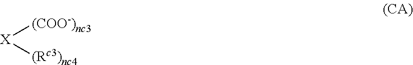
wherein,
X is a C₁₋₂₀ hydrocarbon group,
R^{c3} is each independently hydroxy, C₁₋₆ alkyl or C₆₋₁₀ aryl,
nc3 is 1, 2 or 3, and
nc4 is 0, 1 or 2.

18. The composition according to claim 17, wherein the polymer (A) comprises at least one structural unit selected from the group consisting of the followings:
a structural unit represented by the formula (P-1): 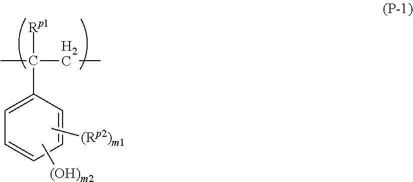
wherein,
R^{p1} is hydrogen, C₁₋₅ alkyl, C₁₋₅ alkoxy or —COOH,
R^{p2} is C₁₋₅ alkyl, where —CH₂— can be replaced with —O—,
m1 is a number of 0 to 4, and
m2 is a number of 1 to 2, and m1+m2≤5;
a structural unit represented by the formula (P-2): 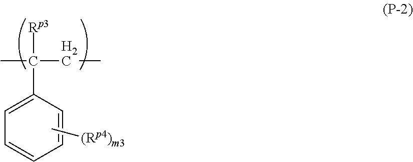
wherein,
R^{p3} is hydrogen, C₁₋₅ alkyl, C₁₋₅ alkoxy or —COOH;
R^{p4} is C₁₋₅ alkyl or C₁₋₅ alkoxy where —CH₂— contained in alkyl or alkoxy can be replaced with —O—, and
m3 is a number of 0 to 5; and
a structural unit represented by the formula (P-3): 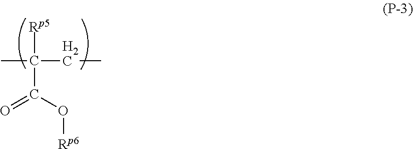
wherein,
R^{p5} is hydrogen, C₁₋₅ alkyl, C₁₋₅ alkoxy or —COOH, and
R^{p6} is C₁₋₁₅ alkyl or C₁₋₅ alkyl ether and R^{p6} can have a cyclic structure,
and nₚ₁, nₚ₂ and nₚ₃, which are the repetition numbers respectively of the formulae (P1), (P2) and (P3), satisfy the following formulae:
40%≤nₚ₁/(nₚ₁+nₚ₂+nₚ₃)≤80%,
3%≤nₚ₂/(nₚ₁+nₚ₂+nₚ₃)≤40%, and/or
10%≤nₚ₃/(nₚ₁+nₚ₂+nₚ₃)≤40%.

19. The composition according to claim 17, wherein the deprotecting agent (B) is represented by the formula (B-1):
Bⁿ⁺cation Bⁿ⁻anion (B-1)
wherein,
Bⁿ⁺cation consists of at least one cation selected from the group consisting of a cation represented by the formula (BC1), a cation represented by the formula (BC2) and a cation represented by the formula (BC3), and is n-valent as a whole and where n is 1 to 3: 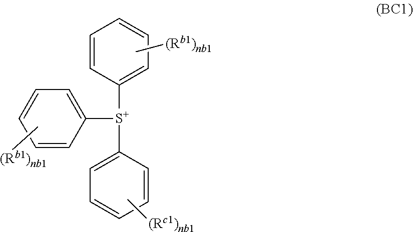
wherein,
R^{b1} is each independently C₁₋₆ alkyl, C₁₋₆ alkoxy, C₆₋₁₂ aryl, C₆₋₁₂ arylthio or C₆₋₁₂ aryloxy, and
nb1 is each independently 0, 1, 2 or 3, 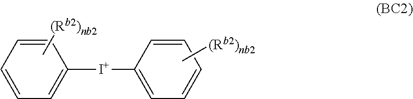
wherein,
R^{b2} is each independently C₁₋₆ alkyl, C₁₋₆ alkoxy or C₆₋₁₂ aryl, and
nb2 is each independently 0, 1, 2 or 3, 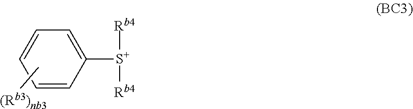
wherein,
R^{b3} is each independently C₁₋₆ alkyl, C₁₋₆ alkoxy or C₆₋₁₂ aryl,
R^{b4} is each independently C₁₋₆ alkyl, and
nb3 is each independently 0, 1, 2 or 3, and
Bⁿ⁻anion consists of at least one anion selected from the group consisting of an anion represented by the formula (BA1), an anion represented by the formula (BA2), an anion represented by the formula (BA3) and an anion represented by the formula (BA4), and is n-valent as a whole: 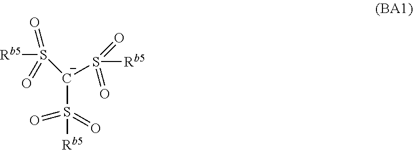
wherein,
R^{b5} is each independently C₁₋₆ fluorine-substituted alkyl or C₁₋₆ alkyl,
R^{b6}—SO₃⁻ (BA2)
wherein,
R^{b6} is C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl; 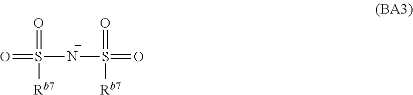
wherein,
R^{b7} is each independently C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl, where two R^{b7} can be bonded to each other to form a fluorine-substituted heterocyclic structure, 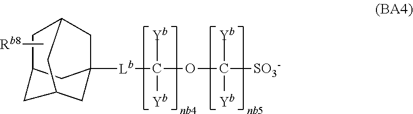
wherein,
R^{b8} is hydrogen, C₁₋₆ alkyl, C₁₋₆ alkoxy or hydroxy,
L^{b} is carbonyl, oxy or carbonyloxy,
Y^{b} is each independently hydrogen or fluorine,
nb4 is an integer of 0 to 10, and
nb5 is an integer of 0 to 21.

20. The composition according to claim 17, wherein the composition can manufacture a resist film having film thickness of 1 to 25 μm.

21. The composition according to claim 17, wherein the composition can manufacture a resist film having film thickness of 1 to 25 μm, and a light source of 248 nm±1% or 193 nm 1% is used upon exposure to be performed later.

22. The composition according to claim 17, wherein
the content of the polymer (A) is 10 to 60 mass % based on the total mass of the composition, and
the content of the photoreaction quencher (C) is 0.01 to 3 mass % based on the total mass of the polymer (A),
the content of the deprotecting agent (B) is 0.05 to 5 mass % based on of the total mass of the polymer (A), and
the content of the solvent (D) is 30 to 90 based on the total mass of the composition.

23. The composition according to claim 17, wherein the composition further comprises a basic compound (E), and the basic compound (E) is ammonia, a C₁₋₁₆ primary aliphatic amine compound, a C₂₋₃₂ secondary aliphatic amine compound, a C₃₋₄₈ tertiary aliphatic amine compound, a C₆₋₃₀ aromatic amine compound or a C5-30 heterocyclic amine compound, and the content of the basic compound (E) is 0 to 2 mass % based on the total mass of the polymer (A).

24. The composition according to claim 17, wherein the deprotecting agent (B) releases an acid having an acid dissociation constant pKa (H₂O) of −20 to 1.4 upon exposure.

25. The composition according to claim 17, wherein the deprotecting agent (B) releases an acid having an acid dissociation constant pKa (H₂O) of −20 to 1.4 upon exposure, the photoreaction quencher (C) releases a weak acid having an acid dissociation constant pKa (H₂O) of 1.5 to 8 upon exposure, and the base dissociation constant pKb (H₂O) of the basic compound (E) is −12 to 5.

26. The composition according to claim 17, wherein the mass average molecular weight (Mw) of the polymer (A) is 5,000 to 50,000, the molecular weight of the deprotecting agent (B) is 400 to 2,500, the molecular weight of the photoreaction quencher (C) is 300 to 1,400, and the molecular weight of the basic compound (E) is 17 to 500.

27. The composition according to claim 17, wherein the mass average molecular weight (Mw) of the polymer (A) is 5,000 to 25,000, the molecular weight of the deprotecting agent (B) is 400 to 1,500, the molecular weight of the photoreaction quencher (C) is 300 to 1,200, and the molecular weight of the basic compound (E) is 60 to 400.

28. The composition according to claim 17, wherein the composition further comprises a plasticizer (F) and further comprises an additive (G), which is at least one selected from the group consisting of surfactants, dyes, contrast enhancers, acids and substrate adhesion enhancers, and the content of the plasticizer (F) is 0 to 20 mass % based on the total mass of the polymer (A), and the content of the additive (G) is 0 to 20% by weight based on the total weight of the polymer (A).

29. The composition according to claim 17, wherein the solvent (D) is water, a hydrocarbon solvent, an ether solvent, an ester solvent, an alcohol solvent, a ketone solvent, or any combination of any of these.

30. The composition according to claim 17, wherein the thick film resist composition is a positive type chemically amplified thick film resist composition.

31. A method for manufacturing a resist film comprising the following processes:
(1) applying the composition according to claim 17 above a substrate; and
(2) heating the composition to form a resist film.

32. A method for manufacturing a resist film comprising the following processes:
(1) applying the composition according to claim 17 above a substrate; and
(2) heating the composition to form a resist film, wherein, the heating in (2) is performed at 100 to 250° C. and/or for 60 to 300 seconds, and, the heating in (2) is performed in the air or a nitrogen gas atmosphere.

33. A method for manufacturing a resist pattern comprising the following processes:
manufacturing the resist film by the method according to claim 31 which further comprises:
(3) exposing the resist film; and
(4) developing the resist film.

34. The method according to claim 33, wherein the method further comprises a process of post exposure bake between (3) and (4), and
wherein ITW, FTW, IBW, and FBW satisfy:
ITW−FTW≤400 nm, and/or
IBW−FBW≤50 nm
where,
ITW is the width at the top part between the resist walls and IBW is the width at the bottom part when the resist pattern is formed by the method according to claim 33 upon setting the time from exposure to post exposure bake to be 1 minute, and
FTW is the width at the top part between the resist walls and FBW is the width at the bottom part when the resist pattern is formed by the method according to claim 33 upon setting the time from exposure to post exposure bake to be 30 minutes.

35. A method for manufacturing a processed substrate comprising the following processes:
manufacturing a resist pattern by the method according to claim 34; and
(5) processing with the resist pattern as a mask,
wherein, the (5) is to process an underlayer film or a substrate.

36. A method for manufacturing a device comprising the method according to claim 31.
